(19) United States
(12) Patent Application Publication
(10) Pub. No.: US 2010/0254138 A1
(43) Pub. Date: Oct. 7, 2010

(54) Light emitting device

(75) Inventors: Yu-Liang Chen, Taichung (TW); Ting-Fang Lai, Taichung (TW)

Correspondence Address: Genius Electronic Optical Co., Ltd., P.O. Box 215, Taichung, 40099, TW

(73) Assignee: Genius Electronic Optical Co., Ltd.

(21) Appl. No.: 12/461,048

(22) Filed: Jul. 30, 2009

(30) Foreign Application Priority Data
Apr. 3, 2009 (TW) 098205451

(51) Int. Cl. H01L 33/00; F21V 5/00

(52) U.S. Cl. 362/236

(57) ABSTRACT

A light emitting device includes a circuit substrate showing a long strip and having a plurality of luminous bodies and a plurality of locking holes spaced at proper intervals along a long side direction; a plurality of optical lenses corresponding to the plurality of luminous bodies disposed on the circuit substrate, in which the optical lens covers the front of the luminous surface of the luminous bodies on the circuit substrate, and has a platform that comprises an incident plane composed of a concave curved surface for accommodating the luminous body and an emitting plane composed of a convex curved surface; and a seal cover plate for fitting and positioning the plurality of optical lenses and having a plurality of through holes and locking holes along the long side direction, in which the through holes can align the plurality of optical lenses.

### FIELD OF THE INVENTION

The present invention relates to a light emitting device, and more particularly to a structural improvement arranged in a long strip and composed of a plurality of light emitting diodes, a plurality of optical lenses aligning the amount of the light emitting diodes, and a seal cover plate.

### BACKGROUND OF THE INVENTION

A conventional illuminating device capable of generating long strip type light source includes a first surface and a second surface disposed on a strip type component; a plurality of heat dissipation fins disposed on the first surface; and a plurality of individual light source components detachably fastened to the second surface. Every individual light source component includes at least one light emitting diode. The light emitting diode of every individual light source component is soldered on a metal made circuit board. A lens is further disposed on the light emitting diode. Every individual light source component includes an upper lid for protecting the light source component. The strip type component includes a T-shape notch. Every individual light source component is fastened on the second surface of the strip type component through a screw and a nut. The nut is disposed in the T-shape notch and the nut is matched with the screw.

The drawbacks of the foregoing structure are that: the plurality of light source components is installed and fastened to the strip type component one by one. While in installation, every set of light source component must be locked to the strip type component by incorporating with two screws and two nuts. Such the structural design may quite consume labor forces and have time consuming during the installation. The upper lid assembled to the front of the light source component is correspondingly installed one by one to cause time consuming in assembly as well.

Further, according to the foregoing conventional structure, the distance of the plurality of light source components disposed on the strip type component is too big. Consequently, the illumination for the effect illuminating area is not uniform and the illumination brightness is weaker.

Accordingly, to overcome the foregoing shortcoming, the inventor(s) of the present invention based on years of experience in the related field to conduct extensive researches and experiments for the technology of the illumination device, and finally invented a light emitting device.

### SUMMARY OF THE INVENTION

A primary objective of the present invention is to provide a light emitting device that has simple assembly and capable of improving the brightness and uniformity of an illuminating area.

To achieve the foregoing objective, the light emitting device provided by the present invention comprises a circuit substrate, a plurality of optical lenses and a seal cover plate. The circuit substrate has a plurality of luminous bodies spaced at intervals. The plurality of luminous bodies is arranged in a single row and a strip shape. A plurality of locking holes is disposed between the preset adjacent luminous bodies on the circuit substrate. The amount of the plurality of optical lenses is matched with the amount of the luminous disposed on the circuit substrate. The optical lens has a platform. An exterior surface of the platform comprises an incident plane and an emitting plane. The incident plane is a concave curved surface for accommodating the luminous body. The emitting surface is a convex curved surface. The concave curved surface and the convex curved surface are composed of a portion area of ellipse surfaces. In addition, the platform comprises symmetric posts at two corresponding sides of the incident plane, and the symmetric posts can lean against the circuit substrate. The seal cover plate can fit and position the plurality of optical lenses. The seal cover plate has a plurality of through holes and locking holes along the long side. The plurality of through holes can be passed by the incident plane of the optical lens. The plurality of locking holes of the seal cover plate can align the plurality of locking holes of the circuit substrate. Accordingly, the seal cover plate can be directly locked and positioned to a lamp holder by incorporating with a plurality of screws passing through the locking holes so that the plurality of luminous bodies distributed as the long strip and having smaller distance is formed to achieve the functions of improving the brightness and uniformity of the illuminating area.

### BRIEF DESCRIPTION OF THE DRAWINGS

FIG. 1 is a decomposition drawing illustrating a structure according to a preferred embodiment of the present invention;

FIG. 2 is an assembly drawing illustrating a structure according to a preferred embodiment of the present invention;

FIG. 3 is a cross-sectional drawing of front view assembly illustrating the structure according to a preferred embodiment of the present invention;

FIG. 4 is a cross-sectional drawing of side view assembly illustrating the structure according to a preferred embodiment of the present invention;

FIG. 5 is a reference drawing I illustrating the implement status of the structure according to a preferred embodiment of the present invention;

FIG. 6 is an assembly drawing according to FIG. 5;

FIG. 7 is a front view assembly drawing according to FIG. 5; and

FIG. 8 is a side view cross-sectional drawing according to FIG. 7.

### DETAILED DESCRIPTION OF THE PREFERRED EMBODIMENTS

Other features and advantages of the present invention will become apparent from the following description of the invention which refers to the accompanying drawings.

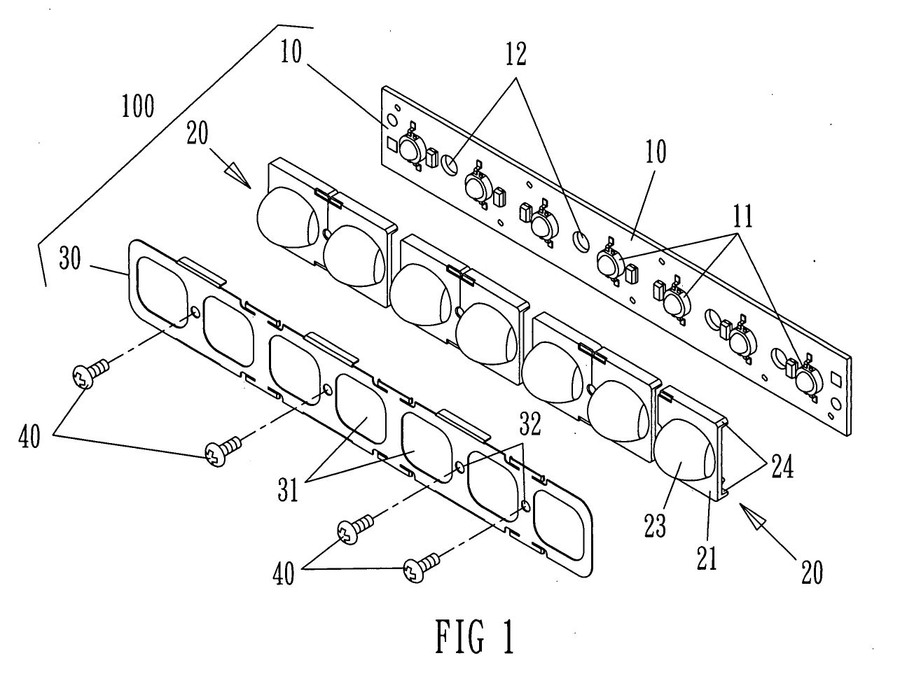

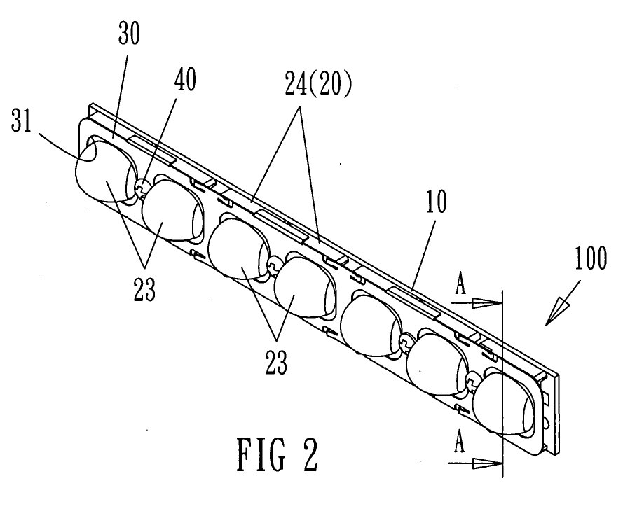

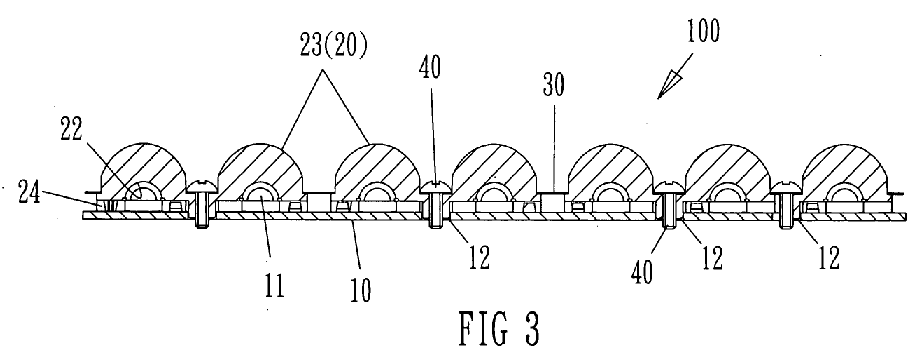

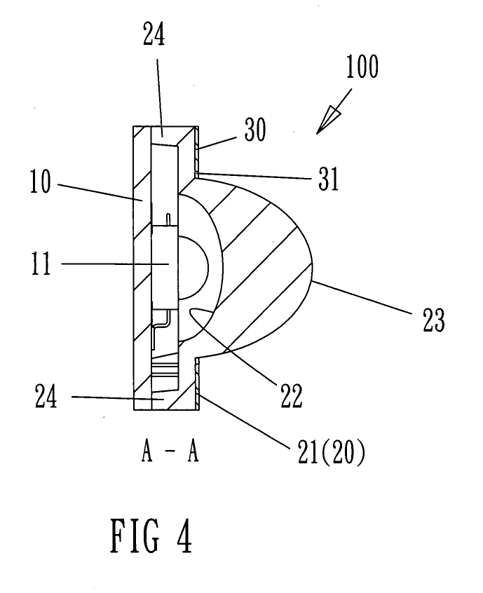

First, please refer to FIG. 1 to FIG. 4, a light emitting device 100 is shown according to a circuit substrate 10 installed with a plurality of luminous bodies 11; a plurality of optical lenses 20 assembled to a front of a luminous surface of every luminous body 11 on the circuit substrate 10; and a seal cover plate 30 capable of fitting and positioning the plurality of optical lenses 20 so as to form the plurality of luminous bodies 11 spaced at intervals and showing single row distribution.

The structural characteristics of components shown in the present invention are continuously illustrated in detail.

The circuit substrate 10 is a longer strip, and has the plurality of luminous bodies 11 spaced at intervals along a long side direction. The plurality of luminous bodies 11 are arranged in single row and the circuit substrate 10 has multiple locking holes 12 disposed between adjacent luminous bodies 11. The luminous bodies 11 shown in the embodiment adopt a kind of LED (light emitting diode).

The amount of optical lenses 20 is matched with the amount of luminous bodies 11 disposed on the circuit substrate 10. The optical lenses 20 mainly comprise a platform 2. The platform 21 has an incident plane 22 and an emitting plane 23 at the same optical axis. The incident plane 22 is a concave curved surface for accommodating the luminous body 11. The emitting plane 23 is a convex curved surface and the concave and convex curved surfaces are composed of a portion area of ellipse surfaces. In addition, the platform 21 has symmetric posts 24 extended at two corresponding sides of the incident plane 22. The symmetric posts 24 directly lean against the circuit substrate 10 to provide proper heat dissipation intervals between the concave curved surface and the luminous body 11.

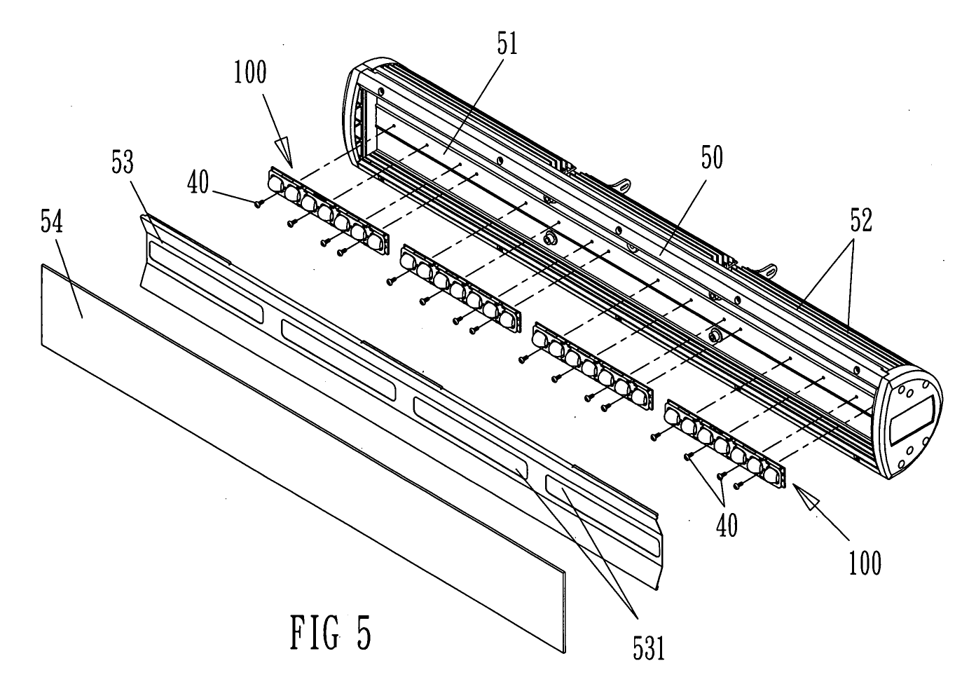

The seal cover plate 30 can insert and position the plurality of optical lenses 20 simultaneously, and has a plurality of through holes 31 and locking holes 32 along the long side. The plurality of through holes 31 can be passed by the incident plane 23 of the optical lens 20. The plurality of locking holes 32 of the seal cover plate 30 can align the plurality of locking holes 12 of the circuit substrate 10. Accordingly, the plate can be directly locked and positioned to a lamp holder 50 (as shown in FIG. 5) by incorporating with a plurality of screws 40 passing through the locking holes 12 and 32 so that the plurality of luminous bodies 11 distributed as the long strip and having smaller distance is formed to achieve the effects of improving the brightness and uniformity of the illuminating area.

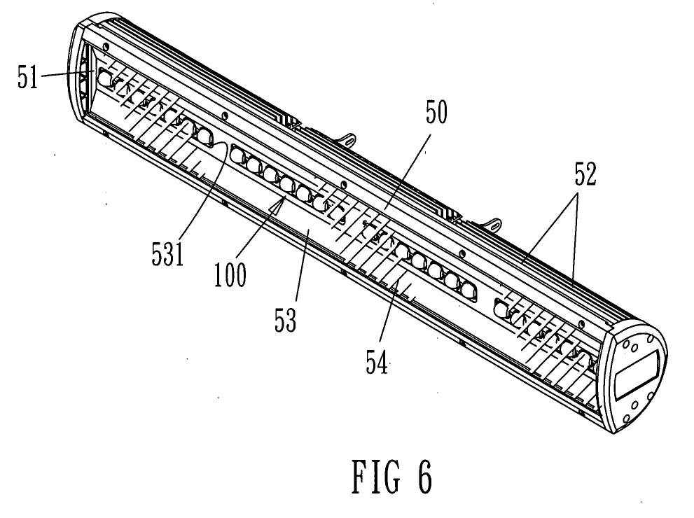

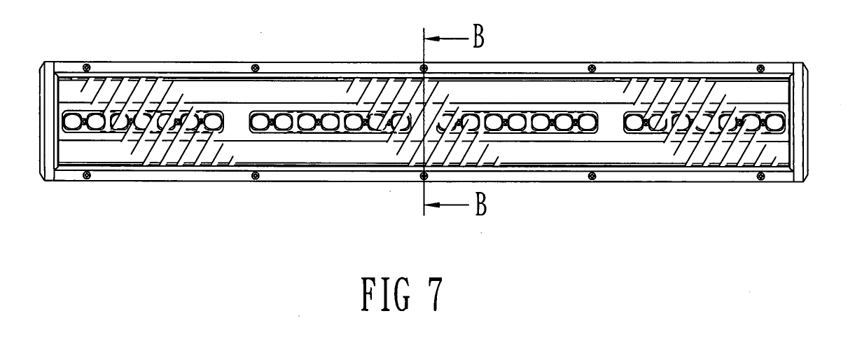

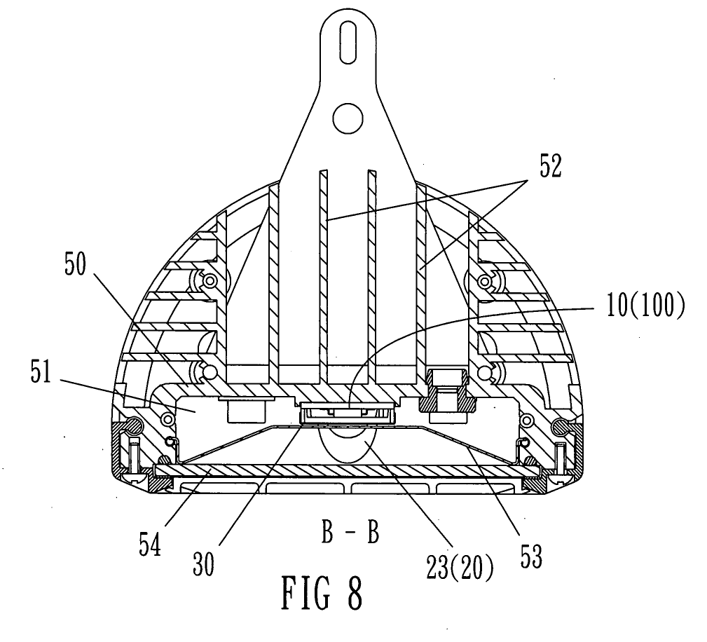

Moreover, as shown in FIG. 5 to FIG. 8, reference drawings of a light emitting device are shown according to preferred embodiment of the present invention. Multiple sets of light emitting devices 100 are cascaded for a single row and assembled in an accommodating slot 51 of a long lamp holder 50 by incorporating with a plurality of screws 40 to provide the high-brightness function. The embodiment arranges four sets of light emitting devices 100 as a row.

Moreover, it does not only arrange multiple sets of light emitting devices as a single row, but also arranges these devices as two rows or more than two rows, or cascades these devices as a triangle, a square, a pentagon or polygons.

It should be noted that a plurality of heat dissipation fins 52 is integrated and extended from a rear of the accommodating slot 51 of the long lamp holder 50. A long reflection plate 53 and a long light transmittance plate 54 are assembled to a front of the accommodating slot 51 of the long lamp holder 50 in order. The reflection plate 53 has a plurality of long shape holes 531 along a long side direction of the reflection plate. Every long shape hole 531 can fit and limit the emitting planes 23 of the plurality of optical lenses 20 of a light emitting device 100 set simultaneously. The light transmittance plate 54 can seal an opening of the front side of the accommodating slot 51.

Although the features and advantages of the embodiments according to the preferred invention are disclosed, it is not limited to the embodiments described above, but encompasses any and all modifications and changes within the spirit and scope of the following claims.

What is claimed is:

1. A light emitting device comprising: a circuit substrate having a plurality of luminous bodies arranged in a single row; a plurality of optical lenses disposed to a front of a luminous surface of every luminous body on the circuit substrate; and a seal cover plate for fitting and positioning the plurality of optical lenses.

2. The light emitting device as claimed in claim 1, wherein the circuit substrate is a long type strip.

3. The light emitting device as claimed in claim 1, wherein the circuit substrate comprises a plurality of locking holes disposed between the predetermined adjacent luminous bodies, and the seal cover plate comprises a plurality of locking holes, and the plurality of locking holes of the circuit substrate correspond to the plurality of locking holes of the seal cover plate.

4. The light emitting device as claimed in claim 1, wherein the luminous body is a light emitting diode.

5. The light emitting device as claimed in claim 1, wherein the optical lens comprises a platform, and an exterior surface of the platform comprises an incident plane and an emitting plane, and the incident plane is a concave curved surface for accommodating the luminous body, and the emitting surface is a convex curved surface.

6. The light emitting device as claimed in claim 5, wherein the concave curved surface and the convex curved surface are composed of a portion area of ellipse surfaces.

7. The light emitting device as claimed in claim 5, wherein the platform comprises symmetric posts at two corresponding sides of the incident plane, and the symmetric posts lean against the circuit substrate.
